(19) United States
(12) Patent Application Publication
(10) Pub. No.: US 2026/0317901 A1
(43) Pub. Date: Oct. 15, 2026

(54) METHOD OF ATOMIC LAYER DEPOSITION

(71) Applicant: Indian Institute of Science, Bangalore (IN)

(72) Inventors: Anil Yadav, Bangalore (IN); Sreekanth Maddaka, Bangalore (IN); Aditya Sadhanala, Bangalore (IN)

(73) Assignee: Indian Institute of Science, Bangalore (IN)

(21) Appl. No.: 19/552,042

(22) Filed: Feb. 27, 2026

(30) Foreign Application Priority Data
Mar. 28, 2025 (IN) 202541030709

(51) Int. Cl. C23C 16/455; C23C 16/44

(52) U.S. Cl. CPC C23C 16/45527; C23C 16/4408; C23C 16/45553

(57) ABSTRACT

A method for atomic layer deposition includes providing a solution-based precursor containing an organometallic compound dissolved in an organic solvent. The deposition process involves introducing the solution-based precursor into a deposition chamber, holding a substrate and maintaining the solution-based precursor in a specific state within the deposition chamber for a predetermined time. Following this, the deposition chamber is purged to remove residual precursor before introducing a co-reactant. The controlled process results in the formation of a film on the substrate, where the film comprises a conformal layer with a uniform thickness.

### TECHNICAL FIELD

The present disclosure relates to atomic layer deposition. Moreover, the present disclosure relates to a method of atomic layer deposition.

### BACKGROUND

Atomic Layer Deposition (ALD) is a widely used technique for depositing thin films with high uniformity, conformality, and precise thickness control. ALD is employed in semiconductor manufacturing, optoelectronics, energy storage, and protective coatings. The method of ALD involves exposing a substrate to sequential, self-limiting reactions of gaseous precursors, ensuring atomic-level control over film growth. However, conventional ALD processes require high-purity organometallic or metal halide precursors that are often pyrophoric, hazardous, and expensive. Additionally, the process is typically performed at elevated temperatures, limiting compatibility with temperature-sensitive substrates such as perovskites and organic materials.

In the existing method of atomic layer deposition (ALD), precursors are delivered in gaseous form, requiring specialized delivery systems, inert gas purging, and high-temperature conditions to ensure efficient reaction kinetics. The existing method presents several challenges. The use of organometallic and metal halide precursors poses safety risks due to the pyrophoric nature of organometallic and metal halide precursors, making their handling, storage, and transport hazardous. Additionally, high-temperature ALD processes limit the deposition of materials on the substrate that degrade at high temperatures, restricting compatibility with sensitive substrates such as perovskites and organic materials. The reliance on high-purity precursors significantly increases costs. Moreover, the complexity of handling highly reactive gaseous precursors necessitates sophisticated equipment and precise control mechanisms, making the integration of ALD into existing semiconductor and optoelectronic manufacturing processes more challenging.

Therefore, in light of the foregoing discussion, there exists a need to overcome the aforementioned drawbacks.

### SUMMARY

The present disclosure provides a method of atomic layer deposition (ALD). The present disclosure addresses the technical problem of how to handle the hazardous precursor and high processing temperature limitations of the precursor in ALD processes. An aim of the present disclosure is to provide a solution that overcomes at least partially the problems encountered in the prior art and provides an improved method of atomic layer deposition featuring a solution-based precursor that reduces the processing temperature and quantity of precursor used during the ALD process.

One or more objectives of the present disclosure is achieved by the solutions provided in the enclosed independent claims. Advantageous implementations of the present disclosure are further defined in the dependent claims.

In one aspect, the present disclosure provides a method of atomic layer deposition comprising:
providing a solution-based precursor comprising an organometallic compound dissolved in an organic solvent;
performing atomic layer deposition to form a film on a substrate by:
   introducing the solution-based precursor into a deposition chamber containing the substrate;
   maintaining the solution-based precursor in a state within the deposition chamber for a predetermined time period; purging the deposition chamber;
   introducing a co-reactant into the deposition chamber;
wherein the film comprises a conformal layer having a uniform thickness.

By dissolving organometallic compounds in organic solvents and maintaining them static or in a continuous flow within the deposition chamber, the method enables safer handling of precursor materials while eliminating the need for pyrophoric pure precursors traditionally used in ALD processes. The static exposure during the predetermined time period allows sufficient interaction between precursor molecules and the substrate surface, enabling effective film formation even at lower temperatures. The controlled deposition process, coupled with systematic purging and co-reactant introduction steps, results in the formation of conformal films with uniform thickness. The method thus overcomes key limitations of conventional ALD processes by reducing safety risks associated with precursor handling while maintaining the high-quality film characteristics essential for various electronic and optoelectronic applications.

It is to be appreciated that all the aforementioned implementation forms can be combined. All steps that are performed by the various entities described in the present application, as well as the functionalities described to be performed by the various entities, are intended to mean that the respective entity is adapted to or configured to perform the respective steps and functionalities. It will be appreciated that features of the present disclosure are susceptible to being combined in various combinations without departing from the scope of the present disclosure as defined by the appended claims.

Additional aspects, advantages, features, and objects of the present disclosure would be made apparent from the drawings and the detailed description of the illustrative implementations construed in conjunction with the appended claims that follow.

### BRIEF DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those in the art will understand that the drawings are not to scale. Wherever possible, like elements have been indicated by identical numbers.

Embodiments of the present disclosure will now be described, by way of example only, with reference to the following diagrams wherein:

FIG. 1 is a flowchart of a method for atomic layer deposition, in accordance with an embodiment of the present disclosure;

FIG. 2 is a diagram illustrating custom-built atomic layer deposition system, in accordance with an embodiment of the present disclosure;

FIG. 3 is a diagram illustrating a single cycle of atomic layer deposition, in accordance with an embodiment of the present disclosure;

FIG. 4A is a first graphical representation illustrating an X-ray diffraction (XRD) pattern of zinc oxide films deposited using ALD at 75 degrees Celsius, in accordance with an embodiment of the present disclosure;

FIG. 4B is a second graphical representation illustrating an X-ray diffraction pattern of zinc oxide films deposited using ALD at 100 degrees Celsius, in accordance with an embodiment of the present disclosure;

FIG. 4C is a third graphical representation illustrating an X-ray diffraction pattern of zinc oxide films deposited using ALD at 130 degrees Celsius, in accordance with an embodiment of the present disclosure;

FIG. 4D is a fourth graphical representation illustrating an X-ray diffraction pattern of zinc oxide films deposited using ALD at 150 degrees Celsius, in accordance with an embodiment of the present disclosure;

FIG. 5A is a graphical representation illustrating the transfer characteristics of a zinc oxide transistor at 100 degrees Celsius, in accordance with an embodiment of the present disclosure;

FIG. 5B is a graphical representation illustrating the transfer characteristics of a zinc oxide transistor at 130 degrees Celsius, in accordance with an embodiment of the present disclosure;

FIG. 6A is a graphical representation illustrating the output characteristics of the zinc oxide transistor at 75 degrees Celsius, in accordance with an embodiment of the present disclosure;

FIG. 6B is a graphical representation illustrating the output characteristics of the zinc oxide transistor at 100 degrees Celsius, in accordance with an embodiment of the present disclosure; and

FIG. 6C is a graphical representation illustrating the output characteristics of the zinc oxide transistor at 130 degrees Celsius, in accordance with an embodiment of the present disclosure.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practicing the present disclosure are also possible.

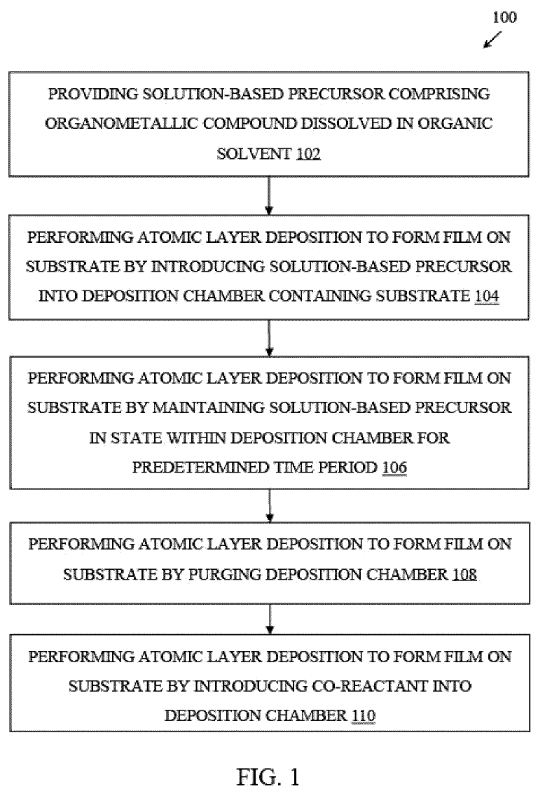

FIG. 1 is a flowchart of a method of atomic layer deposition, in accordance with an embodiment of the present disclosure. With reference to FIG. 1, there is shown a flowchart of a method 100 for atomic layer deposition (ALD). The method 100 is executed at a custom-built ALD tool. The method may include steps 102 to 110.

At step 102, the method 100 includes providing a solution-based precursor comprising an organometallic compound dissolved in an organic solvent. The solution-based precursor comprises the organometallic compound and the organic solvent. In some implementations, the solution-based precursor includes metal halide, and metal pseudohalide dissolved in the organic solvent. The organometallic compound is dissolved in the organic solvent and is used to facilitate uniform deposition in the ALD process. The organometallic compound serves as a metal source, while the organic solvent ensures stability and controlled delivery of the solution-based precursor to a deposition chamber.

In an implementation, the organometallic compound is selected from the group consisting of metal alkyls, metal alkylamides, metal alkoxides, metal amidinates/guanidinates, metal halides, metal pseudohalides, cyclopentadienyls (metallocenes), heteroleptic complexes, carbonyls, and metal β-diketonates. The organometallic compound is selected to ensure desirable precursor reactivity and film deposition in the ALD process. Metal alkyls, metal alkoxides, and metal β-diketonates have high volatility and controlled decomposition properties. For instance, diethylzinc (DEZ), a metal alkyl, is commonly employed for zinc oxide (ZnO) deposition, while titanium isopropoxide (TTIP), a metal alkoxide, is used for titanium dioxide (TiO₂) deposition. The DEZ and TTIP provide a reliable metal precursor that enables efficient surface reactions and uniform film growth on a substrate. The substrate refers to the material on which a film is deposited during the atomic layer deposition (ALD) process. The film comprises a conformal layer having a uniform thickness. The substrate serves as the foundation for film growth, providing reactive surface sites where solution-based precursor molecules can adsorb and undergo chemical reactions. The substrate can be composed of various materials, including silicon, glass, metals, polymers, organic compounds, inorganic compounds or their composites, depending on the intended application of the deposited film.

In another implementation, the organic solvent is selected from the group consisting of but not limited to hexane, chlorobenzene, chloroform, xylene, anisole, toluene, tetrahydrofuran, pentafluorobenzene, isopropyl alcohol, and ethanol. The organic solvent is selected to dissolve the organometallic compound while maintaining precursor stability and reactive metal source for suitable film deposition. The organic solvents such as hexane, toluene, and tetrahydrofuran (THF) dissolve the organometallic compound without unwanted side reactions. For example, toluene is suitable for dissolving DEZ and prevents premature decomposition of the solution-based precursor. The use of an appropriate organic solvent facilitates smooth precursor transport, leading to enhanced film uniformity, reduced impurity incorporation, and improved process efficiency.

The solution-based precursor can have a concentration of any range. In an exemplary scenario, the solution-based precursor concentration between 0.8 molarity (M) and 1.2M. Such concentration range of the solution-based precursor is selected to balance the solution-based precursor vapour pressure and reactivity. The concentration of the solution-based precursor below 0.8M may result in insufficient coverage of the surface of the substrate during each ALD cycle. In contrast, concentrations above 1.2M can lead to uncontrolled gas-phase reactions and poor film uniformity. The concentration around 1M enables consistent delivery of the solution-based precursor and surface reactions at low temperatures. Such concentration range of the solution-based precursor leads to the formation of films with suitable structural properties.

The solution-based precursor improves precursor utilization and reduces precursor wastage compared to conventional solid or gaseous precursors. The solution-based precursor allows for lower deposition temperatures, reducing the thermal degradation of the substrate. Additionally, the controlled vaporization of the solution-based precursor results in improved uniformity of the film.

At step 104, the method 100 includes performing atomic layer deposition (ALD) to form the film on the substrate by introducing the solution-based precursor into the deposition chamber containing the substrate. The atomic layer deposition (ALD) process begins with introducing the solution-based precursor into the deposition chamber containing the substrate. The solution-based precursor is pulsed into the deposition chamber for a predefined time through precisely controlled solenoid valves. The introduction of the solution-based precursor is done at a base pressure to ensure uniform distribution of the solution-based precursor vapour throughout the deposition chamber volume. For example, when depositing ZnO films, the diethylzinc solution is introduced onto the substrate maintained at temperatures between 75 degrees Celsius and 100 degrees Celsius, where it reacts with surface of the substrate in a self-limiting manner. Specifically, once the surface of the substrate is fully covered, no further DEZ can stick to the surface of the substrate. The temperature of the substrate is precisely regulated between room temperature and 400 °C. In an implementation, the substrate is maintained at a temperature below 100 degrees Celsius during the atomic layer deposition. The atomic layer deposition process is performed while maintaining the substrate temperature below 100 degrees Celsius throughout the atomic layer deposition cycles. The temperature control is achieved through a heated substrate holder in the deposition chamber. For instance, ZnO films are successfully deposited at temperatures as low as 75 °C, demonstrating crystalline film growth well below conventional ALD temperatures of 150 °C or higher. The low-temperature processing is useful for depositing films on temperature-sensitive substrates such as but not limited to organic and perovskite materials, which would degrade at higher temperatures.

At step 106, the method 100 includes performing atomic layer deposition (ALD) to form the film on the substrate by maintaining the solution-based precursor in a state within the deposition chamber for a predetermined time period. In some implementations, the solution-based precursor is maintained in a stationary state within the deposition chamber for a predetermined time period. The atomic layer deposition (ALD) process forms the film by maintaining the solution-based precursor in a stationary state within the deposition chamber. Specifically, after introducing the solution-based precursor into the deposition chamber, all inlet and outlet valves are closed to create an isolated environment where the solution-based precursor remains stationary (not flowing) for the predetermined time period. The stationary state is achieved by stopping the flow of the solution-based precursor and sealing the deposition chamber, allowing the solution-based precursor molecules to interact with the substrate surface without continuous flow or dilution. For example, when depositing ZnO on the surface of the substrate using diethylzinc solution in hexane, the solution-based precursor (in this example, DEZ) is held stationary in the chamber for 3 seconds at 75 °C. The stationary exposure allows solution-based precursor molecules to remain in contact with the surface of the substrate. Thereby, ensuring the reaction of the molecules of the solution-based precursor with the surface of the substrate at low temperature. The low temperature (below 100 degrees Celsius) is important for solution-based precursors, with lower vapour pressure than conventional pure precursors.

In another implementation, performing atomic layer deposition (ALD) to form the film on the substrate comprises maintaining the solution-based precursor in a flow state within the deposition chamber. In the flow state ALD process, an inert gas flows continuously in the deposition chamber with simultaneous chamber evacuation throughout the deposition process. The inert gas is maintained at a specified flow rate through the deposition chamber while the solution-based precursor is introduced through precisely controlled solenoid valves, with pulse durations in the millisecond range. Following the precursor exposure, the deposition chamber is purged using the continuous inert gas flow for a predetermined time period to ensure complete removal of excess solution-based precursor molecules. Subsequently, the co-reactant is introduced into the deposition chamber, followed by another inert gas purge cycle before initiating the next ALD cycle. The flow state enables efficient precursor delivery and removal, ensuring consistent film growth through precisely controlled exposure and purge sequences. The pre-determined time period includes pre-determined exposure or precursor hold time period in the deposition chamber. In some implementations, the predetermined time period is between 1 milliseconds and 3 days. The atomic layer deposition process maintains the solution-based precursor in the deposition chamber for the predetermined time period between 1 milliseconds and 3 days during each ALD cycle. The timing is precisely controlled through automated solenoid valves, where the precursor exposure time is suitable for different materials. For instance, in ZnO deposition using diethylzinc solution, a 3-second hold time is employed at 75 °C. The 3-second time window ensures sufficient interaction time between the solution-based precursor and the surface of the substrate at low temperatures. Setting the pre-determined time between 1 milli seconds and 3 days range allows complete surface coverage of the substrate while preventing excessive consumption of the solution-based precursor, leading to well-controlled film growth.

In another implementation, maintaining the solution-based precursor in the state comprises holding the precursor in the deposition chamber without gas flow for a reaction period between 1 millisecond to 2 seconds sufficient to form a monolayer. The atomic layer deposition process can be performed by maintaining the solution-based precursor in either the stationary state or the flow state within the deposition chamber. The atomic layer deposition process involves maintaining the solution-based precursor in a stationary condition by completely stopping the flow of vapours of the solution-based precursor in the deposition chamber for a specific reaction period. Such stationary condition is achieved by closing all inlet and outlet valves after introducing the solution-based precursor, creating an isolated environment where the molecules of the solution-based precursor can interact with the surface of the substrate to form the monolayer.

Alternatively, in the flow state, the precursor exposure is controlled through continuous inert gas flow, where the precursor pulse duration and gas flow rates are optimized to achieve surface coverage similar to the stationary state. For instance, a 50-millisecond precursor pulse with continuous nitrogen flow at 200 standard cubic centimetres per minute (sccm) can achieve comparable film quality.

At step 108, the method 100 includes performing atomic layer deposition (ALD) to form the film on the substrate by purging the deposition chamber. The atomic layer deposition (ALD) process includes a step where the deposition chamber is cleared of excess reactants and byproducts between solution-based precursor exposures, known as purging. The purging is done in atomic layer deposition (ALD) to remove excess solution-based precursor molecules and byproducts from the deposition chamber before introducing the next reactant. The purging prevents unwanted gas-phase reactions and ensures that film growth occurs exclusively through surface reactions. The gas-phase reactions refer to chemical reactions that occur between precursor molecules in the vapour phase rather than on the substrate surface. In atomic layer deposition (ALD), gas-phase reactions are undesirable because they lead to uncontrolled film growth, particle formation, and film contamination. In a typical ALD cycle, a metal precursor (e.g., diethylzinc for ZnO deposition) is introduced first and adsorbs onto the surface of the substrate. Any unreacted solution-based precursor and byproducts must be removed before introducing a co-reactant to prevent direct gas-phase reactions, which can cause uncontrolled deposition, particle formation, or film defects.

In an implementation, purging the deposition chamber comprises purging the deposition chamber with an inert gas. The purging is performed by flowing inert gas while maintaining the base pressure. For example, after the diethylzinc solution exposure step in ZnO deposition, the chamber is purged with nitrogen to remove any unreacted precursor molecules before introducing the water co-reactant. The purging of the deposition chamber ensures the complete removal of excess precursor molecules. The purging prevents any gas-phase reactions between the precursors essential for achieving the self-limiting surface chemistry characteristic of ALD. The thorough purging between precursor steps results in precise thickness control and excellent film uniformity, as demonstrated by the highly crystalline ZnO films with sharp XRD peaks obtained using this process.

In another implementation, the method 100 of atomic layer decomposition further comprises evacuating the deposition chamber to a base pressure after each purging step. The atomic layer deposition process includes evacuating the deposition chamber to a base pressure after each purging step using a vacuum pump connected to the deposition chamber through solenoid valves. For example, during ZnO deposition, the chamber is evacuated to base pressure after purging both the diethylzinc solution exposure and water co-reactant exposure steps. The evacuation of the deposition chamber to a base pressure ensures the complete removal of any residual solution-based precursor molecules and purge gas from the deposition chamber, preventing unwanted gas-phase reactions and cross-contamination between different precursor exposures. Maintaining consistent base pressure between cycles enables precise control over subsequent precursor exposures, resulting in uniform film growth.

At step 110, the method 100 includes performing atomic layer deposition (ALD) to form the film on the substrate by introducing a co-reactant into the deposition chamber. The co-reactant is pulsed into the deposition chamber for a specific duration followed by a hold time to allow complete surface reaction. For instance, in ZnO deposition, water vapour is introduced as the oxidizing co-reactant after the diethylzinc solution step, where it reacts with the metal-containing surface species to form the metal oxide layer. The introduction of the co-reactant completes the surface reaction and converting the adsorbed metal-containing species into the desired film composition. The controlled introduction of co-reactants enables the formation of high-quality films at low temperatures, as evidenced by the n-type behaviour and good on-off ratio observed in ZnO-based field effect transistors fabricated using this process.

In an implementation, the co-reactant is selected from the group consisting of water, oxygen, ozone for oxides, ammonia and hydrazine for nitrides and hydrogen sulfide, 1-cystine, sulfur and HMDS for chalcogenides. The atomic layer deposition process employs specific co-reactants to form different types of thin films through controlled surface reactions with the solution-based precursor. For metal oxide films, co-reactants such as water, oxygen, or ozone are used to form the metal-oxygen bonds through oxidation of the surface-bound metal species. For example, in ZnO deposition, water vapour is pulsed for 100 milliseconds (ms) followed by a 3-second hold time, enabling complete oxidation of the adsorbed diethylzinc species at temperatures as low as 75 °C. When forming metal nitride films, ammonia or hydrazine serves as the nitrogen source, reacting with the metal precursor to form metal-nitrogen bonds. Similarly, for metal chalcogenide films, co-reactants like hydrogen sulfide, sulfur, 1-cystine, or hexamethyldisilathiane (HMDS) provide the chalcogen atoms necessary for film formation. The selection of appropriate co-reactants and the exposure conditions help in achieving complete surface reactions and the desired film composition.

In another implementation, the film comprises one or more of a metal oxide, metal nitride, metal chalcogenide or a combination thereof. The combination of solution-based precursor and co-reactant determines the composition of the film. For example, using diethylzinc solution with water vapour produces zinc oxide films, while using ammonia as the co-reactant would result in metal nitride films. In a specific demonstration, ZnO films are deposited at 75 °C using 1M diethylzinc solution and water vapour, forming a crystalline metal oxide layer with a hexagonal wurtzite structure. The versatility in film composition enables the fabrication of various functional layers needed in electronic and optoelectronic devices.

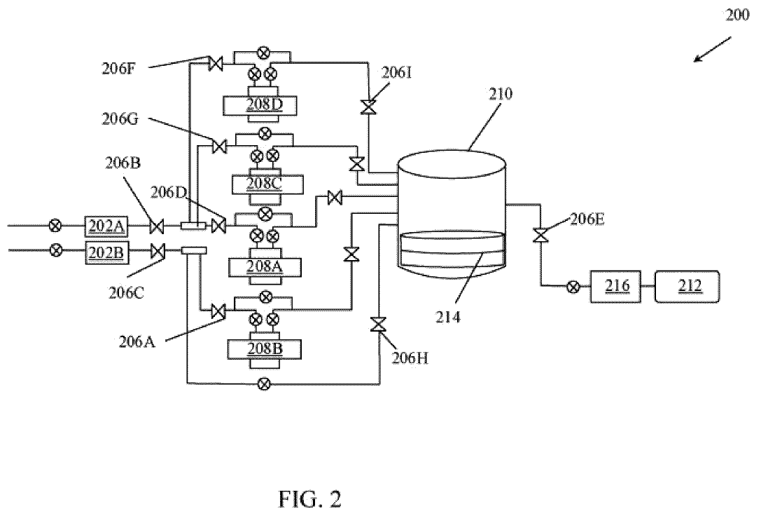

FIG. 2 is a diagram illustrating a custom-built atomic layer deposition system, in accordance with an embodiment of the present disclosure. FIG. 2 is described in conjunction with elements from FIG. 1.

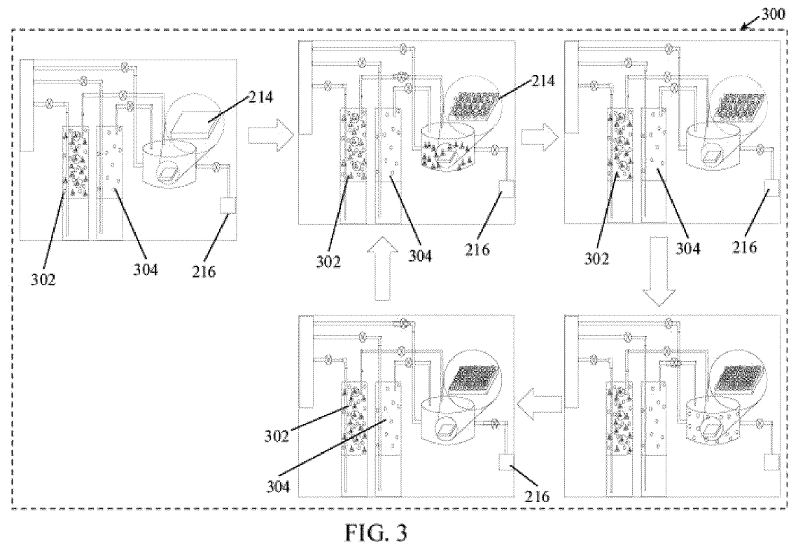

FIG. 3 is a diagram illustrating a single cycle of atomic layer deposition, in accordance with an embodiment of the present disclosure. FIG. 3 is described in conjunction with elements from FIGS. 1 and 2.

With reference to FIGS. 2 and 3, there is shown a custom-built atomic layer deposition system 200 used for depositing thin films using solution-based precursors and a single cycle of atomic layer deposition. The custom-built atomic layer deposition system 200 includes at least two mass flow controllers as illustrated in the embodiment of FIG. 2 a first mass flow controller 202A, a second mass flow controller 202B, a plurality of solenoid valves as illustrated in the embodiment of FIG. 2 a first solenoid valve 206A, a second solenoid valve 206B, a third solenoid valve 206C, a fourth solenoid valve 206D, a fifth solenoid valve 206E, a sixth solenoid valve 206F, a seventh solenoid valve 206G, an eight solenoid valve 206H, a ninth solenoid valve 206I, a plurality of bubblers as illustrated in the embodiment of FIG. 2 a first bubbler 208A, a second bubbler 208B, a third bubbler 208C, a fourth bubbler 208D, a deposition chamber 210, an abatement unit 212, a substrate 214, and a vacuum pump 216. The custom-built atomic layer deposition system 200 is configured to handle both solution-based precursors and co-reactants in a controlled manner through precisely timed valve operations. The single cycle of atomic layer deposition 300 includes a solution-based precursor 302 and a co-reactant 304.

In some implementations, the deposition chamber 210 is connected to at least two mass flow controllers for controlling inert gas flow. The deposition chamber 210 is connected to the first mass flow controller 202A and the second mass flow controller 202B that regulate the inert gas flow, with flow rates controlled at 200 sccm during purge step. The first mass flow controller 202A and the second mass flow controller 202B enable accurate gas flow regulation essential for both purging steps and delivery of solution-based precursor, ensuring complete removal of excess precursors and preventing gas-phase reactions.

In another implementation, the deposition chamber 210 is connected to the vacuum pump 216 for evacuating the deposition chamber 210. The vacuum pump 216 enables evacuation of the deposition chamber 210 to a base pressure of 1 millibar (mbar) before deposition and between ALD cycles, ensuring clean deposition chamber conditions for subsequent precursor exposures.

In yet another implementation, the deposition chamber 210 is further connected to the plurality of bubblers through electronically controlled valves. The plurality of bubblers in the ALD process serves as controlled precursor delivery vessels that enable efficient vaporization and transport of solution-based precursor 302 to the deposition chamber 210. To prevent condensation and clogging of precursor vapours, gas lines from the plurality of bubblers to the deposition chamber are heated and can be maintained at temperatures ranging from room temperature to 550 °C. The heating of the gas lines ensures continuous and uniform precursor flow, reducing the risk of deposition inconsistencies due to condensation within transport lines the solution-based precursor.

In the plurality of bubblers, an inert carrier gas is bubbled through the solution-based precursor 302. In the solution-based ALD process, the plurality of bubblers (208A, 208B, 208C, 208D) contain organometallic compounds dissolved in organic solvents, such as diethylzinc in hexane. To accommodate less or non-volatile precursors, the plurality of bubblers includes a heating mechanism that increases the partial pressure of the precursor in the deposition chamber 210. The temperature of the plurality of bubblers can be precisely controlled. The temperature of the plurality of bubblers can be precisely controlled using independent heating elements coupled with temperature sensors and feedback control systems. The heating elements (such as resistive heaters or jacketed heating systems) apply controlled heat to each bubbler of the plurality of bubblers. The temperature sensors continuously monitor the temperature, and a feedback control system (such as a PID controller) adjusts the heating power to maintain the desired temperature. Thereby, ensuring that precursors with low intrinsic vapor pressure can be efficiently transported into the deposition chamber 210 without requiring excessive carrier gas flow. The bubbling action, combined with precise temperature and pressure control, ensures consistent delivery of precursor vapour to the deposition chamber 210, enabling controlled surface reactions of the substrate 214 necessary for uniform film growth.

In operation, the diethylzinc (DEZ) is dissolved in hexane to serve as the solution-based precursor 302, and water serves as the co-reactant 304. In an implementation, the solution-based precursor 302 is introduced into the deposition chamber 210. The ALD cycle begins with the introduction of the solution-based precursor 302 into the deposition chamber 210 containing the substrate 214. The first solenoid valve 206A opens to allow the vapours of the solution-based precursor (DEZ and hexane solution) to enter the deposition chamber 210 for 50 milliseconds (ms), while the second solenoid valve 206B, the third solenoid valve 206C, the fourth solenoid valve 206D, the fifth solenoid valve 206E, the sixth solenoid valve 206F, the seventh solenoid valve 206G, the eight solenoid valve 206H, and the ninth solenoid valve 206I remain closed to maintain the static condition. The walls of the deposition chamber 210 are equipped with integrated heating elements to maintain a uniform temperature throughout the atomic layer deposition process. The walls of the deposition chamber 210 can be heated to a controlled temperature to prevent condensation of precursor vapours on the inner surfaces of the deposition chamber 210. The heating of the walls of the deposition chamber 210 minimizes precursor condensation on the walls of the deposition chamber 210, ensuring consistent precursor distribution and improving overall film uniformity and deposition efficiency.

In another implementation, the solution-based precursor 302 is isolated from gas flow for the predetermined time. During the static condition, the molecules of the solution-based precursor 302 interact with the surface of the substrate 214. During this phase, all valves are closed to maintain the static condition, allowing sufficient time for the surface reaction to complete. In yet another implementation, the deposition chamber 210 is evacuated after the predetermined time. After the predetermined exposure time (e.g. a fixed time up to 3 seconds), the solenoid valves 206B and 206C of the plurality of solenoid valves are opened for purging the deposition chamber through the mass flow controllers 202A and 202B. For purging in the deposition chamber 210, nitrogen gas is used to remove any excess solution-based precursor and reaction byproducts. In an implementation, the nitrogen gas is used at 200 standard cubic centimetres per minute (sccm) for anywhere from 1 millisecond to 10 minutes.

In some implementations, the co-reactant 304 is introduced into the deposition chamber 210 and isolated from gas flow. Following the purge in the deposition chamber 210, the solenoid valve 206D is opened to introduce water vapour (from water, which serves as a co-reactant 304) from the bubbler 208A of the plurality of bubblers into the deposition chamber 210 for 100 ms. The water molecules are maintained in a static condition for a predetermined time. For example, the water molecules are maintained in a static condition for 3 seconds by closing all the solenoid valves. The water molecules react with the metal-containing surface species to form the metal oxide layer. The vacuum pump 216 connected through solenoid valve 206E maintains the base pressure of 1 millibar (mbar) and removes excess solution-based precursors and byproducts during purging. In some implementations, the deposition chamber 210 is evacuated before the next cycle.

The pumping of the deposition chamber 210 down to the base pressure is followed by another nitrogen purge step to remove excess water vapour and reaction products, completing one full ALD cycle. The ALD cycle can be repeated multiple times to achieve the desired film thickness, with each ALD cycle adding a consistent amount of material to the growing film.

The abatement unit 212 ensures the safe handling of exhaust gases. Line purge valves and manual valves provide additional control points for the maintenance and safety of the custom-built atomic layer deposition system 200. The entire process is controlled through precisely timed operation of the solenoid valves, enabling the sequential steps necessary for atomic layer deposition.

The atomic layer deposition process using solution-based precursor 302 achieves conformal film growth with uniform thickness through controlled layer-by-layer deposition, where each cycle deposits exactly one layer of material. The uniformity is achieved by the precise control of precursor exposure and purge cycles, where the solution-based precursor molecules react with all accessible surface sites of the substrate during the stationary hold period.

The custom-built atomic layer deposition system 200 is specifically configured to accommodate solution-based precursors, with the valve arrangement allowing for both dynamic flow and static exposure modes. The configuration of bubblers and valves ensures minimal precursor consumption while maintaining precise control over the deposition process, enabling high-quality film growth at low temperatures.

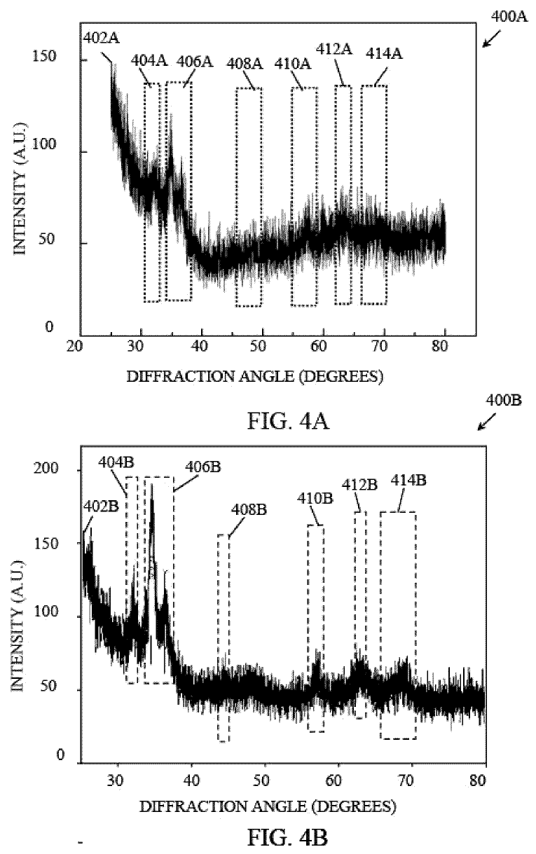

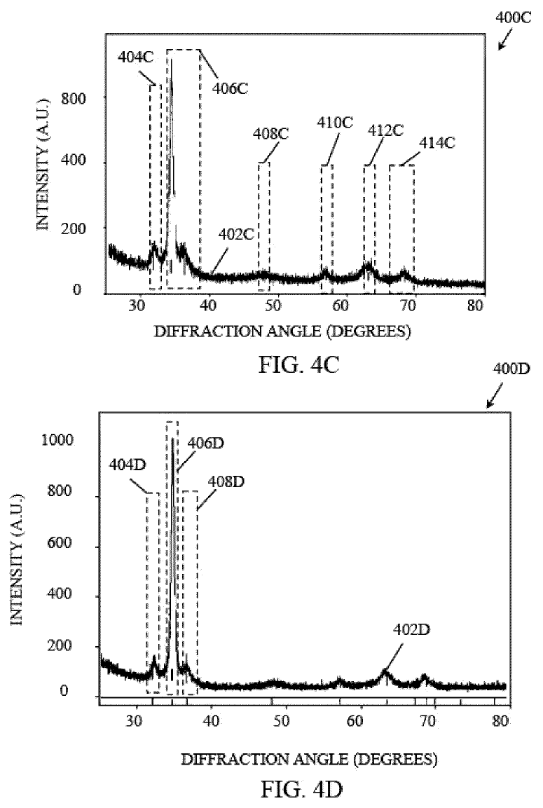

FIG. 4A is a first graphical representation illustrating an X-ray diffraction (XRD) pattern of zinc oxide films deposited using ALD at 75 degrees Celsius, in accordance with an embodiment of the present disclosure. FIG. 4A is described in conjunction with elements of FIGS. 1 to 3. With reference to FIG. 4A, there is shown a first graphical representation 400A illustrating the XRD pattern of zinc oxide films deposited using ALD at 75 degrees Celsius. The first graphical representation 400A illustrating the XRD pattern of zinc oxide films includes a first XRD pattern 402A of the zinc oxide films deposited using ALD. The XRD pattern 402A includes a plurality of diffraction peaks represented by different dotted box. The plurality of peaks includes a first diffraction peak which corresponds to crystallographic plane “(100)” represented by a first dotted box 404A, a second diffraction peak which corresponds to crystallographic planes “(002)” and “(101)” represented by a second dotted box 406A, a third diffraction peak which corresponds to crystallographic plane “(102)” represented by a third dotted box 408A, a fourth diffraction peak which corresponds to crystallographic plane “(110)” represented by a fourth dotted box 410A, a fifth diffraction peak which corresponds to crystallographic plane “(103)” represented by a fifth dotted box 412A and a sixth diffraction peak which corresponds to crystallographic planes “(200)”, “(112)” and “(201)” represented by a sixth dotted box 414A.

XRD is used to identify the crystallographic structure, composition, and physical properties of materials. Peaks in the XRD pattern correspond to atomic planes in a crystal lattice, and their intensities relate to the number of such atomic planes and the orientation of the crystals. The diffraction angle denoted by 2θ is measured in degrees in an abscissa axis. The intensity is expressed in arbitrary units (a.u.) in an ordinate axis. Peaks at specific 2θ degrees values indicate the presence of specific crystallographic planes. Higher peaks indicate more atoms arranged in the corresponding crystallographic plane. The first graphical representation 400A illustrating the XRD pattern of zinc oxide films deposited using ALD includes peaks at 2θ values corresponding to specific crystallographic planes of the zinc oxide films.

The first XRD pattern 402A shows distinct diffraction peaks corresponding to various crystallographic planes of zinc oxide films. The presence of well-defined peaks indicates that the zinc oxide films deposited at 75 degrees Celsius exhibit a crystalline hexagonal wurtzite structure. The first dotted box 404A shows the diffraction peak (at approximately 31.7 degrees) corresponding to the crystallographic plane (100). The second dotted box 406A encompasses two prominent peaks (around 34.4 and 36.2 degrees), corresponding to the crystallographic planes (002) and (101), respectively. The third dotted box 408A highlights the peak (at about 47.5 degrees) corresponding to the crystallographic plane (102), while the fourth dotted box 410A shows the peak (at approximately 56.6 degrees) representing the (110) plane. The fifth dotted box 412A indicates the peak (at about 62.8 degrees) corresponding to the (103) plane, and the sixth dotted box 414A encompasses peaks (around 66-69 degrees) representing the (200), (112), and (201) planes. The presence of these crystallographic planes in the XRD pattern demonstrates that high-quality crystalline zinc oxide films can be successfully deposited using the solution-based ALD process at a relatively low temperature of 75 degrees Celsius, which is significantly lower than conventional ALD processes that typically require temperatures above 150 degrees Celsius.

The intensity of diffraction peaks indicates that the zinc oxide film still exhibits satisfactory level of crystallinity at 75 degrees Celsius. The broad and weak peaks suggest that the deposited zinc oxide does have some amorphous or nanocrystalline domains that do not demonstrate well-defined crystalline structure.

The diffraction peaks correspond to zinc oxide crystallographic planes, but the low intensity and broad nature of the diffraction peaks indicate decreased crystallinity compared to higher temperatures. At 75 degrees Celsius, the molecules of the solution-based precursor do not have enough energy for complete surface reactions with the surface of the substrate and atomic rearrangement, leading to a less ordered film. Therefore, the zinc oxide deposition at 75 degrees Celsius results in films with low crystallinity that while demonstrating good electronic and optical properties, still falls short of those demonstrated by zinc oxide formed at higher temperatures. Overall, the presence of characteristic diffraction peaks in the first XRD pattern 402A confirms the successful formation of crystalline zinc oxide films with hexagonal wurtzite structure even at the low deposition temperature of 75 degrees Celsius. The first XRD pattern 402A for zinc oxide films deposited at 75 degrees Celsius demonstrates that the crystallization process remains incomplete at 75 degrees Celsius. For improved crystallinity, higher deposition temperatures (greater than 75 degrees Celsius) are required to promote better atomic mobility and phase formation of the solution-based precursor with the surface of the substrate.

FIG. 4B is a second graphical representation illustrating an X-ray diffraction (XRD) pattern of zinc oxide films deposited using ALD at 100 degrees Celsius, in accordance with an embodiment of the present disclosure. FIG. 4B is described in conjunction with elements of FIGS. 1 to 3. With reference to FIG. 4B, there is shown a second graphical representation 400B illustrating the XRD pattern of zinc oxide films deposited using ALD at 100 degrees Celsius. The second graphical representation 400B illustrating the XRD pattern of zinc oxide films includes a second XRD pattern 402B of the zinc oxide films deposited using ALD. The second XRD pattern 402B includes a plurality of diffraction peaks represented by different dotted box. The plurality of peaks includes a first diffraction peak which corresponds to crystallographic plane “(100)” represented by a first dotted box 404B, a second diffraction peak which corresponds to crystallographic planes “(002)” and “(101)” represented by a second dotted box 406B, a third diffraction peak which corresponds to crystallographic plane “(102)” represented by a third dotted box 408B, a fourth diffraction peak which corresponds to crystallographic plane “(110)” represented by a fourth dotted box 410B, a fifth diffraction peak which corresponds to crystallographic plane “(103)” represented by a fifth dotted box 412B and a sixth diffraction peak which corresponds to crystallographic planes “(200)”, “(112)” and “(201)” represented by a sixth dotted box 414B. The diffraction angle denoted by 2θ is measured in degrees in an abscissa axis. The intensity is expressed in arbitrary units (a.u.) in an ordinate axis.

The second dotted box 406B indicates the presence of the diffraction peak (at approximately 34.4 degrees) corresponding to the crystallographic planes (002) exhibiting an orientation along the ordinate axis, indicating a characteristic growth direction for zinc oxide films deposited via ALD. The orientation of the diffraction peak at approximately 34.4 degrees is significant in applications requiring anisotropic electrical and optical properties, such as piezoelectric devices and transparent conducting films. However, the intensity of the diffraction peak at approximately 34.4 degrees remains moderate, suggesting that the zinc oxide film is not fully crystalline at 100 degrees Celsius.

The second dotted box 406B and the third dotted box 408B (approximately at 36.2 degrees, 47.5 degrees) corresponding to the crystallographic plane (101) and crystallographic plane (102) shows the broadening of peaks. The broadening of peaks indicates small grain sizes and the presence of strain or defects within the crystal lattice. At 100 degrees Celsius, the atomic mobility of Zn and O atoms is low, leading to incomplete grain growth and limited structural ordering.

The fourth dotted box 410B and the fifth dotted box 412B corresponding to crystallographic planes (110) and crystallographic plane (103) indicate weaker diffraction peaks (at approximately 56.6 degrees and 62.9 degrees). Further, as the intensity of the crystal lattice typically increases at higher deposition temperatures (greater than 100 degrees Celsius), the zinc oxide film attains better crystallinity.

Compared to the atomic layer deposition at 75 degrees Celsius, the intensity of diffraction peaks has increased, indicating an improvement in the crystallinity of the zinc oxide film. However, the diffraction peaks remain relatively broad and exhibit lower intensity than those observed at higher deposition temperatures (as explained below), suggesting that the zinc oxide film is still in the process of crystallization.

Overall, the second XRD pattern 402B at 100 degrees Celsius signifies that zinc oxide film growth is progressing towards improved crystallinity compared to atomic layer deposition at 75 degrees Celsius. However, the zinc oxide film remains partially amorphous with small crystalline domains. The diffraction peaks (404B, 406B, 408B, 410B, 412B and 414B) confirm the presence of the wurtzite structure of the zinc oxide film, but higher deposition temperatures (greater than 100 degrees Celsius) are required to achieve a well-defined crystalline structure with enhanced grain size and reduced structural defects.

FIG. 4C is a third graphical representation illustrating an X-ray diffraction (XRD) pattern of zinc oxide films deposited using ALD at 130 degrees Celsius, in accordance with an embodiment of the present disclosure. FIG. 4C is described in conjunction with elements of FIGS. 1 to 3. With reference to FIG. 4C, there is shown a third graphical representation 400C illustrating the XRD pattern of zinc oxide films deposited using ALD at 130 degrees Celsius. The third graphical representation 400C illustrating the XRD pattern of zinc oxide films includes a third XRD pattern 402C of the zinc oxide films deposited using ALD. The third XRD pattern 402C includes a plurality of diffraction peaks represented by different dotted box. The plurality of peaks includes a first diffraction peak which corresponds to crystallographic plane “(100)” represented by a first dotted box 404C, a second diffraction peak which corresponds to crystallographic planes “(002)” and “(101)” represented by a second dotted box 406C, a third diffraction peak which corresponds to crystallographic plane “(102)” represented by a third dotted box 408C, a fourth diffraction peak which corresponds to crystallographic plane “(110)” represented by a fourth dotted box 410C, a fifth diffraction peak which corresponds to crystallographic plane “(103)” represented by a fifth dotted box 412C and a sixth diffraction peak which corresponds to crystallographic planes “(200)”, “(112)” and “(201)” represented by a sixth dotted box 414C. The diffraction angle denoted by 2θ is measured in degrees in an abscissa axis. The intensity is expressed in arbitrary units (a.u.) in an ordinate axis.

The first dotted box 404C corresponding to the crystallographic plane (100) (approximately ranging between 31 degrees-32 degrees) signifies the in-plane arrangement of zinc oxide crystallites. The in-plane arrangement refers to the orientation of zinc oxide crystallites parallel to the surface of the substrate. In other words, the crystallographic plane (100), indicated by the first dotted box 404C, is aligned in a way that the atomic structure extends laterally along the plane of the zinc oxide film rather than being perpendicular to the plane of the zinc oxide film. The in-plane arrangement influences the electrical, optical, and mechanical properties of the zinc oxide film, affecting characteristics such as carrier mobility and surface roughness. The sharpness and increased intensity of the diffraction peak indicate improved lateral ordering of the zinc oxide grains compared to lower deposition temperatures (less than 130 degrees Celsius).

The second dotted box 406C indicates the diffraction peak corresponding to the crystallographic plane (002) (appearing at approximately between 34 degrees and 35 degrees), representing the preferred c-axis orientation of the zinc oxide crystallites. The c-axis orientation indicates the orientation of stress around the zinc oxide grain over time. The diffraction peak corresponding to the crystallographic plane (002) suggests vertical alignment of the zinc oxide grains, desirable for many applications, including optoelectronic and piezoelectric devices. The increased intensity and reduced peak broadening at 130 degrees Celsius suggest that the zinc oxide film has achieved better crystallinity and improved columnar growth along the c-axis.

The second dotted box 406C indicates the diffraction peak corresponding to the crystallographic plane (101) (appearing at approximately between 36 degrees and 37 degrees), which is another diffraction peak indicating the overall structural quality. The diffraction peak at the crystallographic plane (101) is sharp and intense, indicating a reduction in structural defects and enhanced grain size of the crystal lattice. The zinc oxide film has undergone significant atomic rearrangement, resulting in better packing and ordering of zinc oxide crystallites.

The third dotted box 408C, the fourth dotted box 410C, and the fifth dotted box 412C indicate the diffraction peaks corresponding to the crystallographic planes (102), (110), and (103). The diffraction peaks further indicate crystallization and confirm that the zinc oxide film exhibits a well-developed wurtzite structure with minimal amorphous content. The presence of multiple well-defined diffraction peaks suggests that zinc oxide deposition at 130 degrees Celsius achieves a balance between the reactivity of the solution-based precursor with the surface of the substrate and atomic mobility, leading to the desirable formation of the wurtzite structure.

As compared to the XRD patterns at 75 degrees Celsius and 100 degrees Celsius, a significant improvement in crystallinity is observed at 130 degrees Celsius. The diffraction peaks are sharper and exhibit higher intensity, indicating enhanced grain growth and a more well-defined crystalline structure. The increase in diffraction peak intensity suggests that the zinc oxide film has transitioned from a nanocrystalline or partially amorphous phase to a more crystalline hexagonal wurtzite structure.

Overall, the XRD pattern at 130 degrees Celsius indicates an enhancement in the quality of the zinc oxide film compared to lower temperatures (less than 130 degrees Celsius). The increased intensity reduced peak broadening and the appearance of additional diffraction peaks, indicating that zinc oxide crystallites have grown larger and more ordered. The improvement in structural properties suggests that zinc oxide deposition at 130 degrees Celsius is highly effective in producing high-quality crystalline films suitable for electronic, optical, and sensing applications.

FIG. 4D is a fourth graphical representation illustrating an X-ray diffraction (XRD) pattern of zinc oxide films deposited using ALD at 150 degrees Celsius, in accordance with an embodiment of the present disclosure. FIG. 4D is described in conjunction with elements of FIGS. 1 to 3. With reference to FIG. 4D, there is shown a fourth graphical representation 400D illustrating the XRD pattern of zinc oxide films deposited using ALD at 150 degrees Celsius. The fourth graphical representation 400D illustrating the XRD pattern of zinc oxide films includes a fourth XRD pattern 402D of the zinc oxide films deposited using ALD. The fourth XRD pattern 402D includes a plurality of diffraction peaks represented by different dotted box. The plurality of peaks includes a first diffraction peak which corresponds to crystallographic plane “(100)” represented by a first dotted box 404D, a second diffraction peak which corresponds to crystallographic plane “(002)” represented by a second dotted box 406D, a third diffraction peak which corresponds to crystallographic plane “(101)” represented by a third dotted box 408D. The diffraction angle denoted by 2θ is measured in degrees in an abscissa axis. The intensity is expressed in arbitrary units (a.u.) in an ordinate axis.

The first dotted box 404D indicating the diffraction peak corresponding to the crystallographic plane “(100)” (located approximately between 31 degrees and 32 degrees), represents in-plane crystallographic arrangement. The sharp and intense nature of the diffraction peak at 150 degrees Celsius indicates substantial grain growth and improved lateral packing of zinc oxide crystallites. The deposited film of zinc oxide exhibits better connectivity between zinc oxide grains, leading to a more stable and uniform structure.

The second dotted box 406D indicating the diffraction peak corresponding to the crystallographic plane “(002)” (located at approximately 34 degrees and 35 degrees), is a dominant reflection, indicating that zinc oxide crystallites have a strong preferential orientation along the c-axis. In other words, the strong preferential orientation about the c-axis means that the majority of the zinc oxide crystallites in the film are aligned in such a way that the c-axis (the vertical axis in the hexagonal wurtzite structure of ZnO) is predominantly perpendicular to the surface of the substrate. Thereby indicating a highly ordered growth pattern where the ZnO grains preferentially grow along the c-axis direction, rather than being randomly oriented. The strong preferential orientation is particularly desirable for optoelectronic and semiconductor applications, as it ensures optimal charge transport and piezoelectric properties. The high intensity of the diffraction peak signifies that the zinc oxide grains are well-aligned in a columnar manner, improving the overall film quality and functional performance.

The third dotted box 408D indicating the diffraction peak corresponding to the crystallographic plane “(002)” (located at approximately between 36 degrees and 37 degrees), further confirms the wurtzite structure of the zinc oxide crystallite. The diffraction peak, along with the corresponding crystallographic planes at “(100)” and “(002)”, suggests that the zinc oxide film is highly crystalline with minimal amorphous content. The presence of sharp and well-defined diffraction peaks in the fourth XRD pattern 402D indicates that atomic diffusion and surface reactions at 150 °C are sufficient to promote efficient crystallization.

As compared to the previous deposition temperatures (75 degrees Celsius, 100 degrees Celsius, and 130 degrees Celsius), the diffraction peaks in the fourth graphical representation 400D exhibit significantly higher intensity and sharper profiles, indicating a well-crystallized zinc oxide film. The increased intensity provides an improved grain growth of the zinc oxide crystal lattice and reduces structural defects, while the sharpness of the diffraction peaks confirms enhanced long-range atomic ordering. At 150 degrees Celius, the zinc oxide film has transitioned into a highly crystalline phase with well-aligned zinc oxide grains, characteristic of the hexagonal wurtzite structure.

Overall, the fourth XRD pattern 402D of zinc oxide films deposited at 150 degrees Celsius indicates desirable crystallization and phase purity. The strong, sharp peaks confirm significant grain growth, enhanced crystallite alignment, and minimal structural defects. The fourth XRD pattern 402D results in a high-quality zinc oxide film suitable for applications in electronics, sensors, and optoelectronic devices.

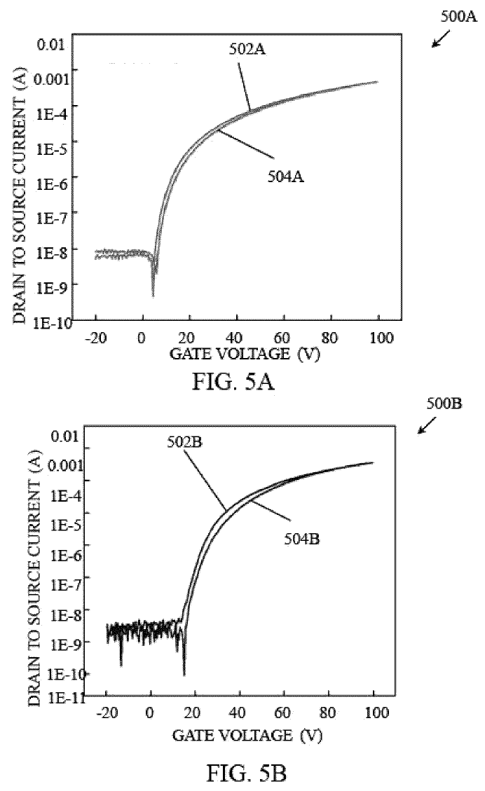

FIG. 5A is a graphical representation illustrating the transfer characteristics of a zinc oxide transistor at 100 degrees Celsius, in accordance with an embodiment of the present disclosure. FIG. 5A is described in conjunction with elements of FIGS. 1 to 4D. FIG. 5B is a graphical representation illustrating the transfer characteristics of a zinc oxide transistor at 130 degrees Celsius, in accordance with an embodiment of the present disclosure. FIG. 5B is described in conjunction with elements of FIGS. 1 to 4D.

With reference to FIGS. 5A and 5B, there are shown graphical representations 500A and 500B, illustrating the transfer characteristics of a zinc oxide transistor. The graphical representation 500A includes a first curve 502A and a second curve 504A. The graphical representation 500B includes a third curve 502B and a fourth curve 504B. The transfer characteristics are useful for evaluating the electrical performance of zinc oxide film, by revealing the underlying charge transport mechanisms and material properties of the zinc oxide film used in the transistor. The gate voltage denoted by V_{g} is measured in voltage (V) on an abscissa axis. The drain to source current denoted by I_{ds} is measured in amperes (A) on an ordinate axis. The transfer characteristics provide insights into the electrical conduction mechanisms, carrier transport behaviour, and the quality of the electrical contacts in the deposited zinc oxide film of the transistor. By analysing the transfer characteristics of the zinc oxide transistor, the electrical properties of the zinc oxide films can be correlated with the deposition parameters, useful for optimizing the performance in electronic applications.

The first curve 502A represents the forward sweep of the transfer characteristics of ALD deposited ZnO at 100 degrees The second curve 504A represents the reverse sweep of the transfer characteristics of ALD deposited ZnO at 100 degrees. The third curve 502B represents the forward sweep of the transfer characteristics of ALD deposited ZnO at 130 degrees. The fourth curve 504B represents the reverse sweep of the transfer characteristics of ALD deposited ZnO at 130 degrees.

The transfer characteristics as illustrated in FIGS. 5A and 5B demonstrate the similarity between the ZnO transistors fabricated using the ideal atomic layer deposition (ALD) process and those developed with the solution-based precursor. The two curves (i.e., 502A, 504A and 502B, 504B), exhibit nearly identical trends in drain-to-source current as a function of gate voltage, indicating that both fabrication methods yield transistors with comparable electrical performance. The close overlap between the first curve 502A and the second curve 504A as shown in FIG. 5A and, the third curve 502B, and the fourth curve 504B, as shown in FIG. 5B show that the ZnO film grown from the solution-based precursor achieves a similar carrier transport behaviour, threshold voltage, and subthreshold characteristics as the film deposited through ideal ALD process. The transistors developed using solution-based precursors do not compromise the transistor operation. The ALD process using solution-based precursors is a useful alternative to the existing ALD process.

The transfer characteristics observed in FIGS. 5A and 5B indicate that the ZnO film deposited using the solution-based precursor exhibits properties consistent with a high-quality n-type semiconductor. The close alignment of the transfer curves for the solution-based precursor ALD process and the ideal ALD process confirms that the film possesses efficient charge carrier transport, low defect states, and a well-defined conduction mechanism. The stability of the drain-to-source current over varying gate voltages suggests that the ZnO film maintains a uniform electronic structure, ensuring reliable transistor operation. The transfer characteristics highlight that despite the lower deposition temperature, the solution precursor atomic layer deposition process successfully produces a ZnO film with electrical performance comparable to that of conventionally grown films, reinforcing its viability for low-temperature electronic applications.

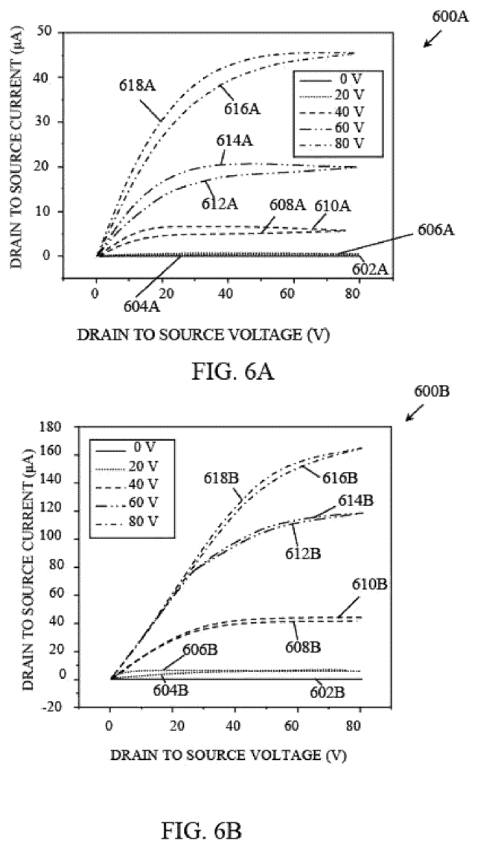

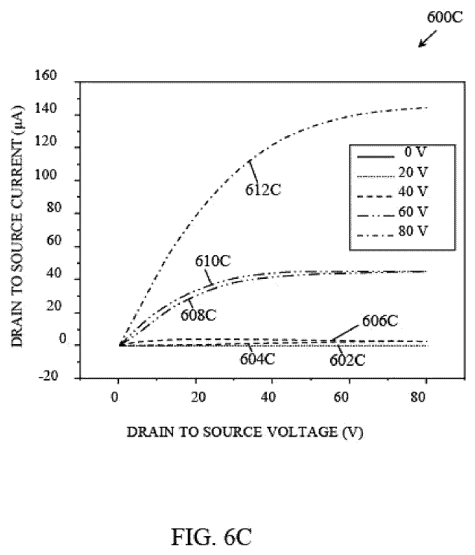

FIG. 6A is a graphical representation illustrating the output characteristics of the zinc oxide transistor at 75 degrees Celsius, in accordance with an embodiment of the present disclosure. FIG. 6A is described in conjunction with elements of FIGS. 1 to 5B. With reference to FIG. 6A, there is shown a graphical representation 600A illustrating the output characteristics of a zinc oxide transistor at 75 degrees Celsius. The graphical representation 600A includes a plurality of curves at different gate voltages. The plurality of curves includes a first curve 602A at 0 volts(V), a second curve 604A and a third curve 606A at 20V, a fourth curve 608A and a fifth curve 610A at 40V, a sixth curve 612A and a seventh curve 614A at 60V, an eight curve 616A and a ninth curve 618A at 80V.

The output characteristics of a transistor represent the relationship between the drain-to-source current (denoted by I_{ds}) measured in micro-amperes (μA) and drain-to-source voltage (denoted by V_{ds}) measured in volts (V) at different gate voltages (0V, 20V, 40V, 60V, and 80V). The output characteristics provide information about the behaviour of the transistor in different operating regions. A linear region at low V_{ds} where the I_{ds} increase linearly with V_{ds}, and a saturation region at higher V_{ds} where the I_{ds} remain relatively constant despite increasing V_{ds}. The output characteristics are illustrated as a family of curves, each measured at a different gate voltage, demonstrating how the gate field modulates the channel conductivity. An analysis of the family of curves exhibits channel conductance, effective mobility, and current drive capability of the transistor. The separation between curves at different gate voltages indicates the effectiveness of gate control over the channel. At the same time, the flatness of the saturation region reflects channel length modulation effects and the overall stability of the transistor.

The first curve 602A, the second curve 604A, and the third curve 606A indicates that the value of drain to source current is minimum, signifying a weakly formed conductive channel with limited charge carrier density. As the gate voltage increases to 40V, the fourth curve 608A and the fifth curve 610A indicates that the conductive channel allows a greater flow of charge carriers, resulting in an increase in drain current (approximately ranging from 1 to 5 μA). At even higher gate voltages of 60V and 80V, the sixth curve 612A to the ninth curve 618A exhibits increased values of drain to source current (approximately ranging between 15 to 55 μA). The increased value of drain to source current indicates strong electrostatic control over the conduction channel and efficient charge carrier transport, thereby improved efficiency of the zinc oxide transistor.

FIG. 6B is a graphical representation illustrating the output characteristics of the zinc oxide transistor at 100 degrees Celsius, in accordance with an embodiment of the present disclosure. FIG. 6B is described in conjunction with elements of FIGS. 1 to 6A. With reference to FIG. 6B, there is shown a graphical representation 600B illustrating the output characteristics of a zinc oxide transistor at 100 degrees Celsius. The graphical representation 600B includes a plurality of curves at different gate voltages. The plurality of curves includes a first curve 602B at 0 V, a second curve 604B and a third curve 606B at 20V, a fourth curve 608B and a fifth curve 610B at 40V, a sixth curve 612B and a seventh curve 614B at 60V, an eight curve 616B and a ninth curve 618B at 80V.

The first curve 602B, the second curve 604B, and the third curve 606B indicate that the drain to source current is minimal, suggesting a weakly formed conductive channel with low charge carrier density. As the gate voltage increases to 40V, the fourth curve 608B and the fifth curve 610B show a higher flow of charge carriers through the channel, leading to an increase in drain current (approximately ranging from 10 to 40 μA). At even higher gate voltages of 60V and 80V, the sixth curve 612B to the ninth curve 618B exhibit significantly increased drain-to-source current values (approximately ranging between 50 to 160 μA). The substantial increase in drain current indicates enhanced electrostatic control over the conduction channel, facilitating efficient charge carrier transport and improved current modulation, thereby demonstrating improved performance of the zinc oxide transistor at the given conditions.

FIG. 6C is a graphical representation illustrating the output characteristics of the zinc oxide transistor at 130 degrees Celsius, in accordance with an embodiment of the present disclosure. FIG. 6C is described in conjunction with elements of FIGS. 1 to 6B. With reference to FIG. 6C, there is shown a graphical representation 600C illustrating the output characteristics of a zinc oxide transistor at 130 degrees Celsius. The graphical representation 600C includes a plurality of curves at different gate voltages. The plurality of curves includes a first curve 602C at 20 V, a second curve 604C and a third curve 606C at 40V, a fourth curve 608C and a fifth curve 610C at 60V, a sixth curve 612A at 80V.

The first curve 602C, the second curve 604C, and the third curve 606C indicate minimal drain to source current, representing a weakly formed conductive channel with low charge carrier density. As the gate voltage increases to 40V, the fourth curve 608C and the fifth curve 610C demonstrate an increase in charge carrier flow, leading to a moderate rise in drain current (approximately ranging from 10 to 35 μA). At even higher gate voltages of 60V and 80V, the sixth curve 612C exhibits a significant increase in drain-to-source current (approximately ranging up to 140 μA). The increase in drain to source current exhibits improved electrostatic control over the conduction channel, leading to efficient charge carrier transport and enhanced current modulation, thereby improving the overall performance of the zinc oxide transistor.

The output characteristics measured at different temperatures (130 °C, 100 °C, and 75 °C) demonstrate that the zinc oxide transistor fabricated using the solution-based precursor exhibits electrical behaviour comparable to existing transistors. The output characteristic family of curves at each temperature shows the expected behaviour of n-type transistor operation, with distinct linear region and saturation region observed across all gate voltages (0V, 20V, 40V, 60V, and 80V).

The output characteristics at different temperatures exhibit that the solution-based precursor can produce zinc oxide transistors with performance metrics comparable to existing transistors, even at temperatures as low as 75 °C. The relationship between drain-to-source current and drain-to-source voltage and gate voltage dependence indicates that the transistors fabricated at low temperatures can effectively function as active elements in electronic circuits, offering an alternative to existing high-temperature ALD processes while maintaining essential characteristics of the transistor.

The method 100 of atomic layer deposition is advantageous through by using solution-based precursors 302 and lower deposition temperature. The method 100 enables safe handling of organometallic compounds by dissolving them in organic solvents, eliminating the hazards associated with pure pyrophoric precursors traditionally used in the process of ALD. The process of ALD operates at temperatures below 100 degrees Celsius, making the process compatible with temperature-sensitive substrates while maintaining precise control over film formation. Through carefully timed cycles of precursor introduction, static exposure, purging, and co-reactant exposure, the method 100 of ALD achieves layer-by-layer growth resulting in conformal films with uniform thickness. The custom-built atomic layer deposition system 200 provides control through mass flow controllers (202A, 202B), vacuum pump 216, and plurality of bubblers (208A, 208B, 208C, 208D) ensures precise delivery of solution-based precursors 302 and efficient purging of deposition chamber 210. The combination of solution-based precursor 302, low-temperature processing, and precise control of the temperature and inert gas in the deposition chamber 210 enables the deposition of high-quality metal oxides, nitrides, and chalcogenides, as demonstrated by the formation of crystalline films suitable for electronic applications. The method 100 of ALD thus overcomes key limitations of existing ALD processes while maintaining the high-quality film characteristics essential for various electronic and optoelectronic devices.

Modifications to embodiments of the present disclosure described in the foregoing are possible without departing from the scope of the present disclosure as defined by the accompanying claims. Expressions such as “including”, “comprising”, “incorporating”, “have”, “is” used to describe and claim the present disclosure are intended to be construed in a non-exclusive manner, namely allowing for items, components or elements not explicitly described also to be present. Reference to the singular is also to be construed to relate to the plural. The word “exemplary” is used herein to mean “serving as an example, instance or illustration”. Any embodiment described as “exemplary” is not necessarily to be construed as preferred or advantageous over other embodiments and/or to exclude the incorporation of features from other embodiments. The word “optionally” is used herein to mean “is provided in some embodiments and not provided in other embodiments”. It is appreciated that certain features of the present disclosure, which are, for clarity, described in the context of separate embodiments, may also be provided in combination in a single embodiment. Conversely, various features of the present disclosure, which are, for brevity, described in the context of a single embodiment, may also be provided separately or in any suitable combination or as suitable in any other described embodiment of the disclosure.

We claim:

1. A method for atomic layer deposition, comprising:
providing a solution-based precursor comprising organometallic compound dissolved in an organic solvent;
performing atomic layer deposition to form a film on a substrate by:
introducing the solution-based precursor into a deposition chamber containing the substrate;
maintaining the solution-based precursor in a state within the deposition chamber for a predetermined time period;
purging the deposition chamber;
introducing a co-reactant into the deposition chamber;
wherein the film comprises a conformal layer having a uniform thickness.

2. The method as claimed in claim 1, wherein the substrate is maintained at a temperature below 100 degrees Celsius during the atomic layer deposition.

3. The method as claimed in claim 1, wherein the organometallic compound is selected from the group consisting of metal alkyls, metal alkylamides, metal alkoxides, metal amidinates/guanidinates, cyclopentadienyls (metallocenes), heteroleptic complexes, carbonyls, metal halides, metal pseudohalides, and metal β-diketonates.

4. The method as claimed in claim 1, wherein the organic solvent is selected from the group consisting of but not limited to hexane, chlorobenzene, chloroform, xylene, anisole, toluene, tetrahydrofuran, pentafluorobenzene, isopropyl alcohol, and ethanol.

5. The method as claimed in claim 1, wherein the co-reactant is selected from the group consisting of water, oxygen, ozone for oxides, ammonia and hydrazine for nitrides and hydrogen sulfide, 1-cystine, sulfur and HMDS for chalcogenides.

6. The method as claimed in claim 1, wherein the film comprises one or more of a metal oxide, metal nitride, or metal chalcogenide or combinations thereof.

7. The method as claimed in claim 1, wherein purging the deposition chamber comprises purging the deposition chamber with an inert gas.

8. The method as claimed in claim 1, further comprises evacuating the deposition chamber to a base pressure after each purging step.

9. The method as claimed in claim 1, wherein the predetermined time period is between 1 milli seconds and 3 days.

10. The method as claimed in claim 1, wherein the solution-based precursor is introduced into the deposition chamber and isolated from gas flow for the predetermined time period; the deposition chamber is evacuated after the predetermined time period; the co-reactant is introduced into the deposition chamber and isolated from gas flow; and
the deposition chamber is evacuated before the next cycle.

11. The method as claimed in claim 1, wherein maintaining the solution-based precursor in the state comprises holding the solution-based precursor in the deposition chamber without gas flow for a reaction period between 1 millisecond to 2 seconds sufficient to form a monolayer.

12. The method as claimed in claim 1, wherein the deposition chamber is connected to:
at least two mass flow controllers for controlling inert gas flow; and
a vacuum pump for evacuating the deposition chamber; and a plurality of bubblers through electronically controlled valves.
